(19) United States
(12) Patent Application Publication
(10) Pub. No.: US 2025/0081411 A1
(43) Pub. Date: Mar. 6, 2025

(54) VEHICULAR ECU WITH MULTI-CHANNEL COOLING SYSTEM

(71) Applicant: Magna Electronics Inc., Auburn Hills, MI (US)

(72) Inventors: Sateesh Mutaguppe Kamalakar, Karnataka (IN); Deepak Selvaraj, Karnataka (IN); Rajith Jaladihalli Ningappa, Karnataka (IN)

(21) Appl. No.: 18/820,498

(22) Filed: Aug. 30, 2024

Related U.S. Application Data
(60) Provisional application No. 63/580,461, filed on Sep. 5, 2023.

(51) Int. Cl. H05K 7/20

(52) U.S. Cl. CPC H05K 7/20854; H05K 7/20409; H05K 7/20872

(57) ABSTRACT

A vehicular electronic control unit (ECU) includes a housing that accommodates a printed circuit board (PCB). At least one heat-generating electronic component is disposed on the PCB. The ECU includes a plurality of heat dissipating fins disposed at an exterior side of the housing. The heat dissipating fins are disposed within a fluid chamber at the housing, and heat is dissipated from the heat dissipating fins via coolant that flows within the fluid chamber along and between individual heat dissipating fins of the plurality of heat dissipating fins. An inlet port provides flow of coolant into the fluid chamber, and an outlet port provides flow of coolant out of the fluid chamber. The heat dissipating fins provide a multi-channel flow path for coolant within the fluid chamber between the inlet port and the outlet port.

### CROSS REFERENCE TO RELATED APPLICATION

The present application claims the filing benefits of U.S. provisional application Ser. No. 63/580,461, filed Sep. 5, 2023, which is hereby incorporated herein by reference in its entirety.

### FIELD OF THE INVENTION

The present invention relates generally to a vehicle vision system for a vehicle and, more particularly, to a vehicle vision system that utilizes one or more cameras at a vehicle.

### BACKGROUND OF THE INVENTION

Use of imaging sensors in vehicle imaging systems is common and known. Examples of such known systems are described in U.S. Pat. Nos. 5,949,331; 5,670,935 and/or 5,550,677, which are hereby incorporated herein by reference in their entireties.

### SUMMARY OF THE INVENTION

A vehicular electronic control unit (ECU) includes a printed circuit board (PCB) that includes electronic circuitry and a housing that houses the PCB at an interior portion of the housing. The electronic circuitry includes at least one heat generating electronic component disposed on the PCB that, when electrically operated during operation of the vehicular ECU, generates heat at the interior portion of the housing. A plurality of heat dissipating fins are disposed at the exterior side of the housing within the fluid chamber, and the plurality of heat dissipating fins are in thermal conductive connection with the interior portion of the housing. When heat is generated at the interior portion of the housing during operation of the vehicular ECU (such as when one or more data processors within the ECU are operating to process data captured by one or more cameras or sensors of the vehicle), the heat is dissipated from the interior portion of the housing via the plurality of heat dissipating fins. The plurality of heat dissipating fins are disposed within a fluid chamber at the exterior side of the housing. Heat is dissipated from the plurality of heat dissipating fins via coolant that flows along and between the plurality of heat dissipating fins. An inlet port is in fluidic connection with the fluid chamber to provide flow of coolant into the fluid chamber, and an outlet port is in fluidic connection with the fluid chamber to provide flow of coolant out of the fluid chamber. The plurality of heat dissipating fins provide a multi-channel flow path for coolant within the fluid chamber between the inlet port and the outlet port.

These and other objects, advantages, purposes and features of the present invention will become apparent upon review of the following specification in conjunction with the drawings.

### BRIEF DESCRIPTION OF THE DRAWINGS

FIG. 1 is a perspective view of a vehicle with a vision system;

FIG. 2 is a perspective view of a housing portion of an ECU module associated with the vision system;

FIG. 3 is another perspective view of the housing portion of the ECU module of FIG. 2;

FIGS. 4A and 4B show heat dissipating fins near an inlet port of the fluid chamber of the housing portion of the ECU module of FIG. 2;

FIG. 5A is a perspective view of the housing portion of the ECU module of FIG. 2, with the heat dissipating fins removed from the fluid chamber;

FIG. 5B is a perspective view of the housing portion of the ECU module of FIG. 2, with the heat dissipating fins having embedded pins outlined;

FIG. 6A is a sectional view of the inlet port of the housing portion of the ECU module of FIG. 2, with the inlet port offset from the bottom surface of the fluid channels;

FIG. 6B is a sectional view of the inlet port of the housing portion of the ECU module of FIG. 2, with the inlet port aligned with the bottom surface of the fluid channels;

FIG. 7 is a perspective view of a housing portion of another ECU module;

FIG. 7A is an enlarged view of area A in FIG. 7;

FIG. 8 shows example flow paths within the fluid chamber of the housing portion of the ECU module of FIG. 2;

FIG. 8A is an enlarged view of area A in FIG. 8;

FIG. 9 shows example flow paths within the fluid chamber of the housing portion of the ECU module of FIG. 7;

FIG. 9A is an enlarged view of area A in FIG. 9;

FIG. 10 shows an example heat gradient of the housing portion of the ECU module of FIG. 2 during operation of the ECU module; and

FIG. 11 shows an example heat gradient of the housing portion of the ECU module of FIG. 7 during operation of the ECU module.

### DESCRIPTION OF THE PREFERRED EMBODIMENTS

A vehicle vision system and/or driver or driving assist system and/or object detection system and/or alert system operates to capture images exterior of the vehicle and may process the captured image data to display images and to detect objects at or near the vehicle and in the predicted path of the vehicle, such as to assist a driver of the vehicle in maneuvering the vehicle in a rearward direction. The vision system includes an image processor or image processing system that is operable to receive image data from one or more cameras and provide an output to a display device for displaying images representative of the captured image data. Optionally, the vision system may provide display, such as a rearview display or a top down or bird's eye or surround view display or the like.

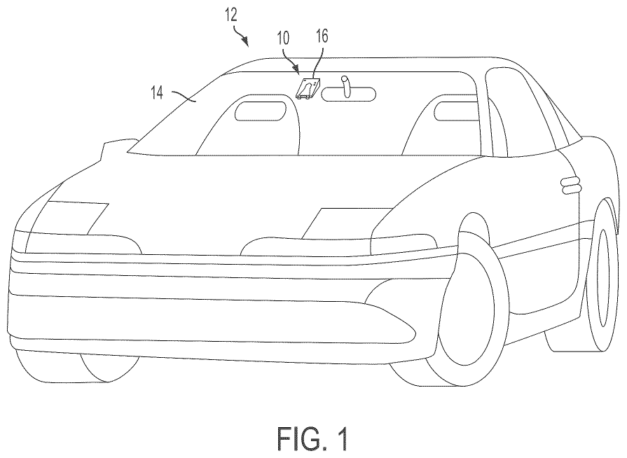

Referring now to the drawings and the illustrative embodiments depicted therein, a vision system 10 for a vehicle 12 includes at least one exterior viewing imaging sensor or camera, such as a forward viewing imaging sensor or camera, which may be disposed at and behind the windshield 14 of the vehicle and viewing forward through the windshield so as to capture image data representative of the scene occurring forward of the vehicle (FIG. 1). Optionally, the system may include multiple exterior viewing imaging sensors or cameras, such as a forward viewing camera at the front of the vehicle, and a sideward/rearward viewing camera at respective sides of the vehicle, and a rearward viewing camera at the rear of the vehicle, which capture images exterior of the vehicle. The camera or cameras each include a lens for focusing images at or onto an imaging array or imaging plane or imager of the camera. The forward viewing camera may be part of a camera module or windshield mounted electronics module (WEM) 16 disposed at the windshield 14 of the vehicle 12 and that views through the windshield and forward of the vehicle, such as for a machine vision system (such as for traffic sign recognition, headlamp control, pedestrian detection, collision avoidance, lane marker detection and/or the like). The vision system 10 includes a control or electronic control unit (ECU) having electronic circuitry and associated software, with the electronic circuitry including a data processor or image processor that is operable to process image data captured by the camera or cameras, whereby the ECU may detect or determine presence of objects or the like and/or the system provide displayed images at a display device for viewing by the driver of the vehicle. The camera module 16 may accommodate the ECU or the ECU may be disposed at any suitable location at the vehicle. The data transfer or signal communication from the camera to the ECU may comprise any suitable data or communication link, such as a vehicle network bus or the like of the equipped vehicle.

Advanced driving assistance systems (ADAS) or vision systems include a significantly increasing number of features and perform an increasing number of functions to both provide additional functionality to consumers and also to meet industry standards and governmental regulations. Additionally, a common or singular or central ECU may process data from various sensors in the vehicle (e.g., exterior viewing camera module, radar sensors, driver/cabin monitoring camera, surround view system cameras, cameras for camera monitoring systems (CMS), and the like) to provide the additional functionality. For example, the ECU module may include one or more printed circuit boards (PCBs) accommodating one or more integrated chips or integrated circuits (ICs) to provide the increased processing. An increased number of features and functions results in a higher demand for processing speed and increased power consumption by ECUs and ADAS modules.

When the ECU provides the additional functionality and increased processing, this may result in greater heat generation at the ECU module. However, requirements for maximum operating ambient temperature of the ECU may require the ECU to operate below a threshold temperature, such as 85 degrees Celsius or less, because operating electronics devices at high temperatures, such as above the threshold temperature, is a challenge. That is, with the growing demand to integrate multiple PCBs and provide multifunctional electronics on one platform, this increases the thermal risks to the ICs and may cause failure.

Thermal solutions to cool the heat generating electrical components and the ECU modules of the vehicle may include natural convection of heat away from the ECU module, forced convection of heat away from the ECU module using fans that direct cooling airflow across heat sinks thermally coupled to the ECU module, and liquid cooling using coolants that draw heat away from the ECU module. Natural convection and forced convection via fan may be limited by the heat carrying capacity and lower heat transfer coefficient of air, and thus may not meet thermal requirements for the ECU module. Liquid cooling, such as with Glycol 50 coolant, may enhance heat transfer away from the ECU module as the coolant has a higher specific heat and heat transfer coefficient. As discussed further below, the ECU module may include a housing or enclosure that is configured to receive coolant and direct coolant along and/or within the housing to dissipate heat from the ECU module to the coolant so that the heated coolant may be directed away from the ECU module to provide cooling to the ECU module.

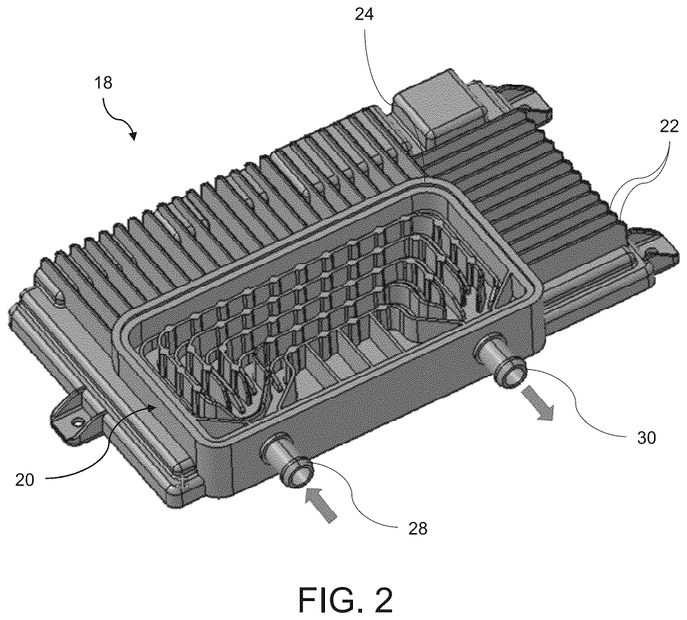

Referring to FIGS. 2-6B, the ECU module includes a first or upper housing portion 18 and the upper housing portion 18 may join or mate with a second or lower housing portion to accommodate one or more heat generating electronic components at an interior portion of the ECU housing. The upper housing portion 18 includes a multi-channel liquid jacket or fluid chamber or flow area 20, where coolant may flow along the fluid chamber 20 to dissipate heat away from the upper housing portion 18. For example, the ECU module may accommodate a PCB that includes one or more heat generating electronic components, such as an image processor or data processor, and the one or more heat generating electronic components are in thermally conductive connection with the upper housing portion 18 such that heat generated by the components is dissipated through the upper housing portion 18 to maintain an operating temperature of the electronic components. The upper housing portion 18 may further include a plurality of heat dissipating fins 22 extending from an outer surface of the upper housing portion 18 and outside the fluid chamber 20 so that the fins 22 may draw heat away from the heat generating electronic components and airflow (e.g., ambient airflow or directed airflow from a cooling fan) may dissipate heat away from the fins 22 to provide cooling to the ECU module.

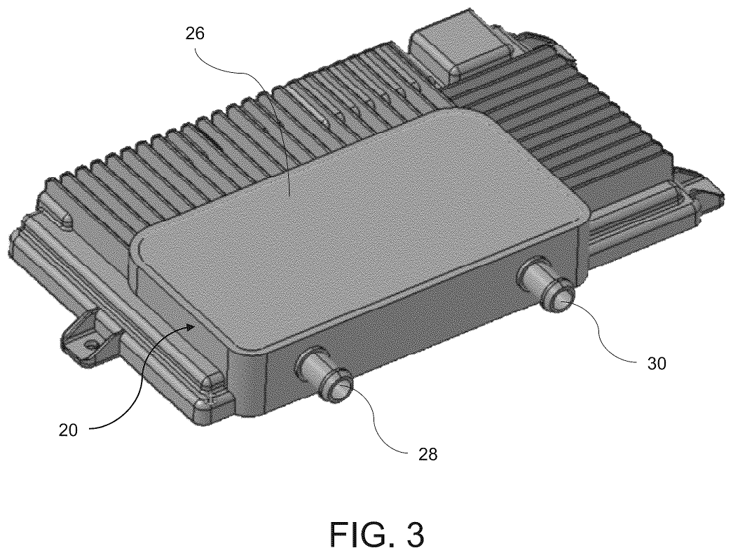

The fluid chamber 20 is fluidically sealed or separated from the interior portion of the ECU module and defines an interior portion or area configured to accommodate flow of coolant through the fluid chamber. In the illustrated example of FIG. 2, the fluid chamber 20 includes outer circumferential walls 24 extending from the outer surface of the upper housing portion 18 and a cover or top plate 26 (FIG. 3) may extend along and between outer edges of the outer walls 24 to seal the fluid chamber 20. For example, the top plate may meet design for manufacturing (DFM) and friction stir welding (FSW) guidelines. FSW may be used to ensure proper sealing for the fluid chamber 20

An inlet port 28 is disposed at the outer wall 24 and supplies flow of coolant to the fluid chamber 20, such as from a coolant reservoir and/or pump, and an outlet port 30 is disposed at the outer wall 24 spaced from the inlet port 28 and directs flow of coolant from the fluid chamber, such as back to the reservoir or pump.

One or more heat dissipating fins or walls define a multi-channel flow path for coolant to flow within the fluid chamber 20 and between the inlet port 28 and the outlet port 30. For example, a plurality of first fins 32 and a plurality of second fins 34 each extend along the outer surface of the upper housing portion 18 within the fluid chamber 20 to form respective channels between the inlet port 28 and the outlet port 30. The channels may be substantially U-shaped to provide uninterrupted flow between the inlet port 28 and the outlet port 30, which are positioned at or near the respective ends of the U-shaped channels. That is, the channels between respective heat dissipating fins may form respective U-shaped paths between the inlet port 28 and the outlet port 30. The first fins 32 and the second fins 34 are in thermally conductive connection with the upper housing portion 18 to increase surface area engaging the coolant as it flows from the inlet port 28 toward the outlet port 30.

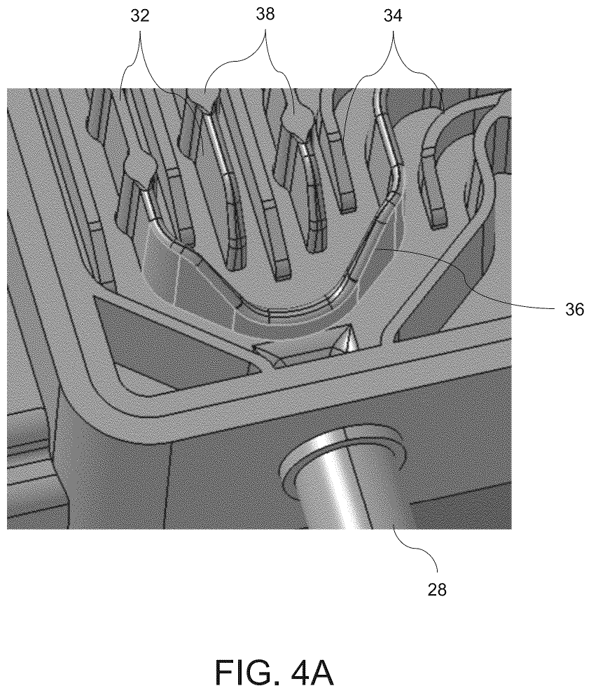

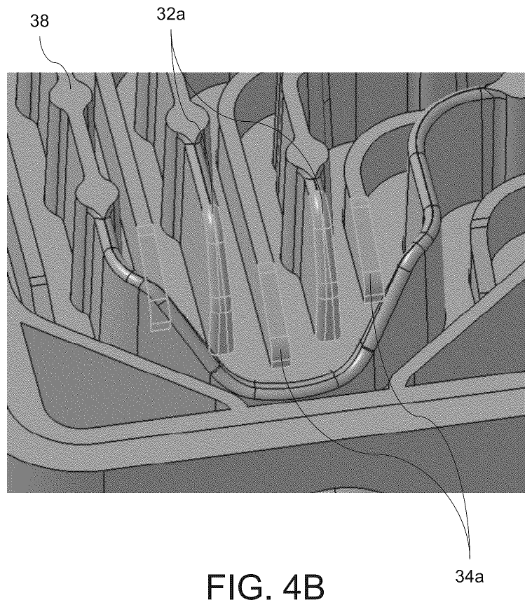

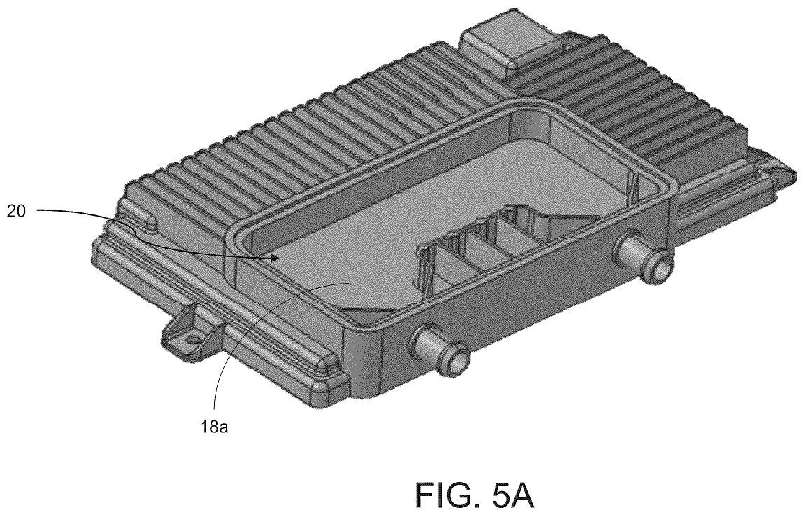

Referring to FIGS. 4A and 4B, coolant entry is through the inlet orifice or port 28 and a valley fin 36 positioned within the fluid chamber 20 at or near the inlet port 28 may direct or distribute the flow of coolant toward the multiple channels. For example, the valley fin 36 extends from the outer surface of the housing portion 18 and may include a shorter central wall portion generally aligned with the inlet port 28 and taller lateral wall portions along opposing sides of the central portion. The lateral wall portions may be connected to respective first fins 32 or second fins 34 and provide a smooth or curved transition between the shorter central wall portion and the taller lateral wall portions and first fins 32 or second fins 34. Thus, the valley fin 36 induces the flow of coolant to scatter and distributes flow entering at higher velocity into the paths of the multiple channels between the first fins 32 and second fins 34. The valley fin 36 is in thermally conductive connection with the upper housing portion 18 and thus enhances heat transfer at the entry or inlet port 28 of the fluid chamber 20 and keeps the flow distributed without any recirculation causing back pressure. The pressure drop is maintained to accommodate pump specifications.

Further, first ends 32a of the first fins 32 and first ends 34a of the second fins 34 at or near the valley fin 36 and the inlet port 28 may be chamfered to avoid shocks due to high velocity flow of coolant. Channels may be formed between alternating first fins 32 and second fins 34, such that respective first fins 32 are disposed between a pair of second fins 34 and respective second fins 34 are disposed between a pair of first fins 32. The second fins 34 provide a straight fin design with smooth or flat side walls. The first fins 32 may provide a straight fin design with rounded portions or protrusions or pins 38 embedded along the first fins 32, such that side walls of the first fins may include waves or protrusions or rounded portions. The embedded pins 38 are positioned along the main straight fins to add turbulence to the flow of coolant and enhance heat transfer between the fins and the coolant by increasing surface area contact.

The straight second fins 34 may increase the surface area that enhances heat transfer between the fins and the coolant. Further, the second fins 34 may be shorter (or extend a shorter distance from the upper housing portion) than the first fins 32 to make efficient flow of coolant at an upper portion of the flow volume. That is, the second fins 34 may be shorter to allow coolant to flow over respective second fins 34 between adjacent flow channels. For example, the second fins 34 may be about 40 percent the height of the first fins 32.

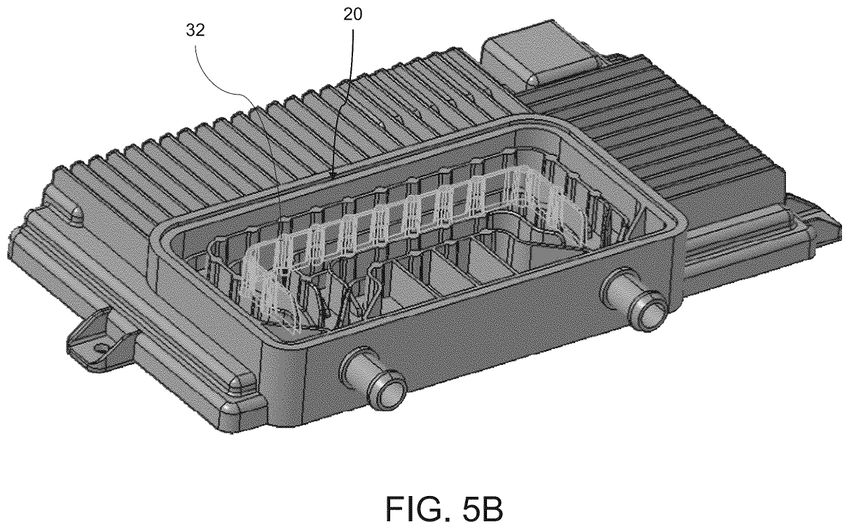

Thus, and as shown in FIGS. 5A and 5B, the first fins 32 and the second fins 34 extend from the upper surface 18a of the upper housing portion 18 within the fluid chamber 20 to increase the surface area for heat transfer from the upper housing portion 18 to the flow of coolant through the chamber 20. Compared to the flat upper surface 18a, the fins may increase surface area by 50 percent or more to enhance heat transfer. That is, the extended surfaces enhance the heat transfer from the flat surface where forced convection heat transfer mode is in action. Inside the fluid compartment or jacket 20, the extended surface area of 50 percent or more induces enhanced heat transfer.

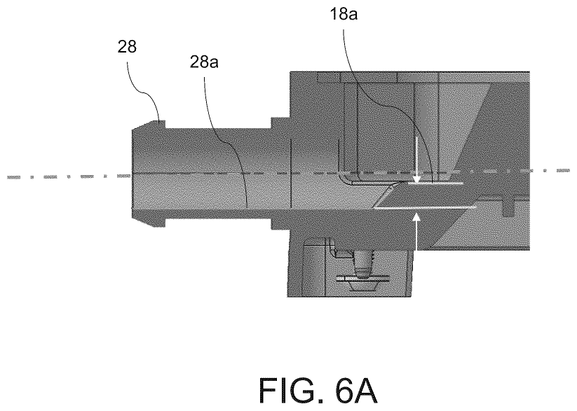

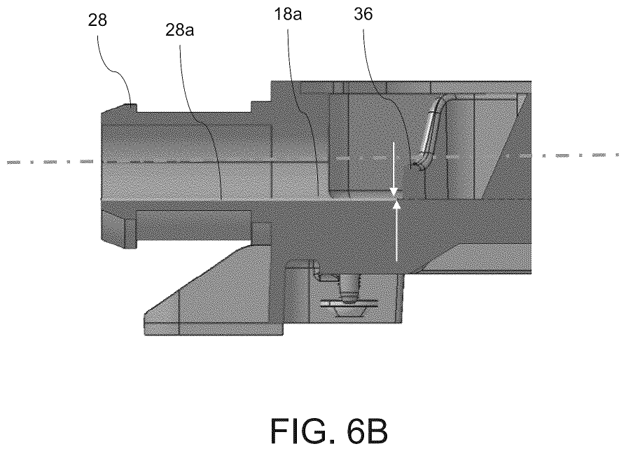

As shown in FIG. 6A, the inlet port 28 may be offset from the bottom surface 18a of the fluid channels so that flow of coolant from the inlet port 28 flows upward and then along the fluid channels upon entry to the fluid chamber 20. That is, a lower surface 28a of the inlet port 28 at the entrance to the fluid chamber 20 is disposed below the upper surface 18a of the upper housing portion 18 (that provides the bottom surface of the fluid channels), such that a central axis or midpoint of the inlet port 28 may be below a central axis or midpoint of the fluid channels. Thus, the flow of coolant is uplifted as it flows from the inlet port 28 into the fluid chamber 20, such as to improve inlet flow and mixing of the flow around the valley fin 36.

Optionally, and such as shown in FIG. 6B, the inlet port 28 may be aligned with the fluid channels so that the lower surface 28a of the inlet port at the entrance to the fluid chamber 20 may align with or be coplanar with the bottom surface 18a of the fluid channels. Thus, there is little to no offset between the lower surface 28a of the inlet port 28 and the bottom surface 18a of the fluid channels and the central axis or midpoint of the inlet port 28 and the central axis or midpoint of the fluid channels may be aligned. With the valley fin 36 at the inlet port 28, the straight flow entry path provides smooth entry at the inlet with improved inlet flow and mixing of flow about the valley fin 36.

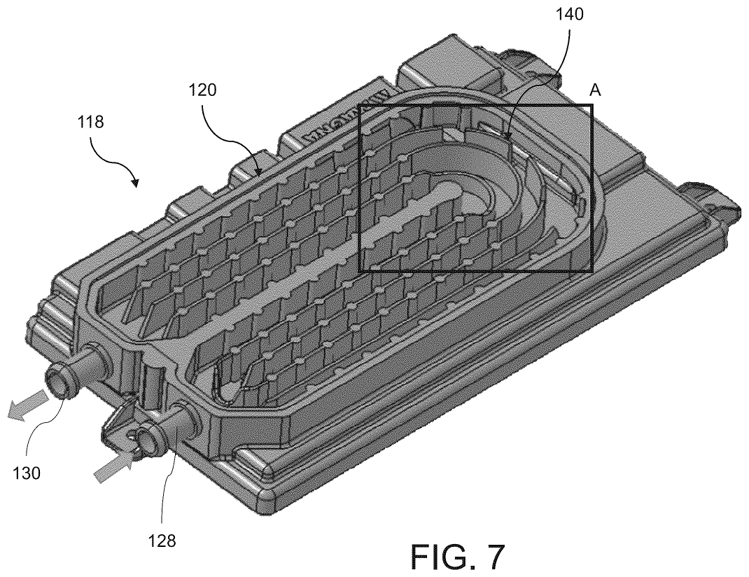

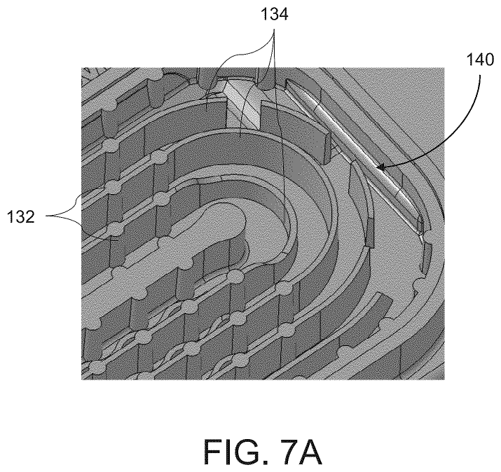

Referring to FIGS. 7 and 7A, an upper housing portion 118 of an ECU module may include a fluid chamber 120 with a mixing section 140 between the inlet port 128 and the outlet port 130. For example, the upper housing portion 118 may include a plurality of first fins 132 and a plurality of second fins 134 arranged within the fluid chamber 120 between the inlet port 128 and the outlet port 130 to provide substantially U-shaped flow paths or channels for coolant. That is, the channels between respective heat dissipating fins may form respective U-shaped paths between the inlet port 128 and the outlet portion 130. The first fins 132 may extend from the inlet port 128 and the outlet port 130 and along the respective straight portions of the U-shaped channels and the second fins 134 may extend between the ends of the first fins 132 at the curved portion of the U-shaped channels. The second fins 134 may be shorter than the first fins 132 and/or one or more gaps or recesses may be formed along the second fins 134 to encourage mixing of coolant between respective channels at the mixing section 140.

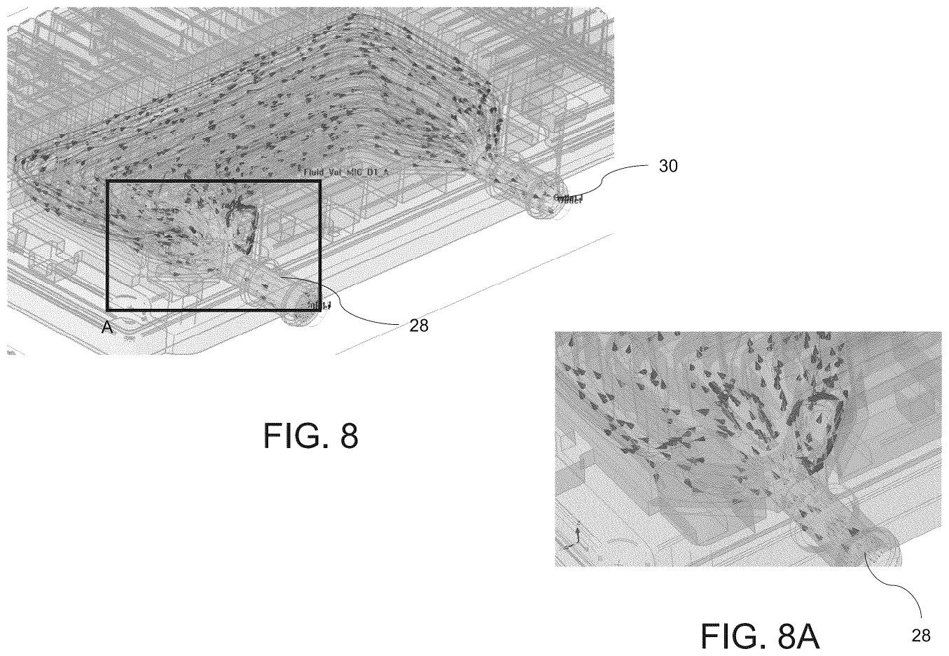

As shown in FIGS. 8 and 8A, the fluid chamber 20 of the upper housing portion 18 may provide a vertical flow path between the inlet port 28 and the outlet port 30. The flow rate of coolant along the multi-channel flow path and between the respective channels may be substantially uniform. That is, a flow rate between respective channels may be optimized to provide enhanced and uniform cooling.

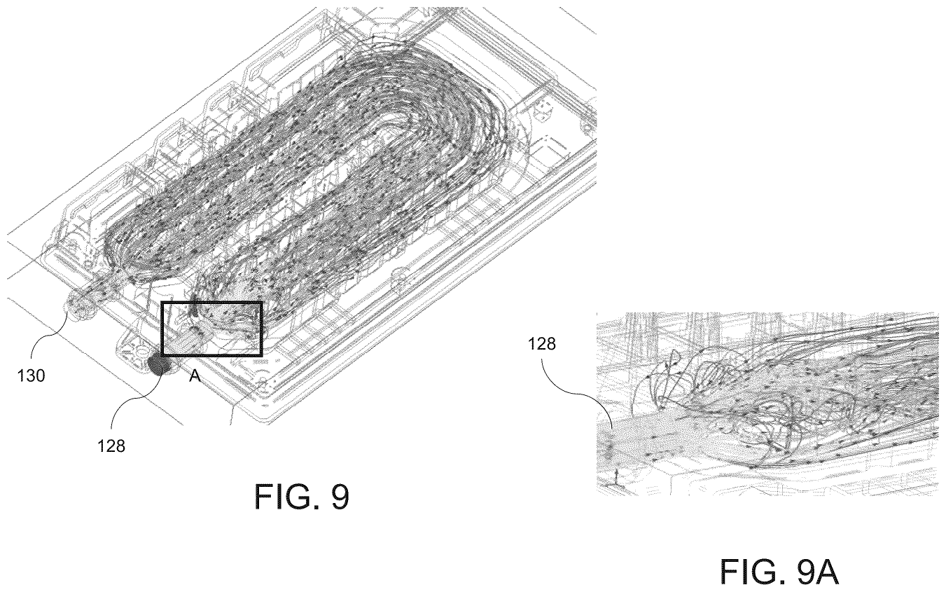

As shown in FIGS. 9 and 9A, the fluid chamber 120 of the upper housing portion 118 may provide a horizontal flow path between the inlet port 128 and the outlet port 130. The flow rate of coolant along the multi-channel flow path and between the respective channels and through the mixing section 140 may be substantially uniform. That is, a flow rate between respective channels may be optimized to provide enhanced and uniform cooling.

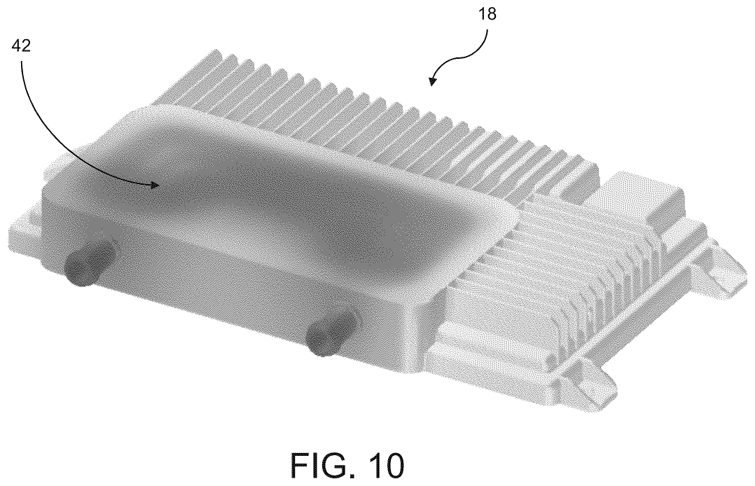

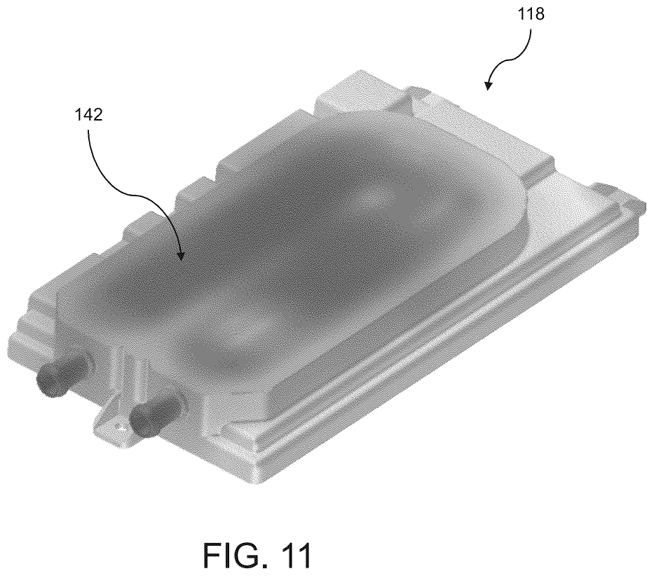

As shown in FIG. 10, the upper housing portion 18 provides enhanced cooling at the fluid chamber 20, such that, during operation of the ECU module and when the heat generating electronic components generate heat that is dissipated by the upper housing portion 18, a cooler region 42 is concentrated at the fluid chamber 20 and presence of hotter regions is limited or reduced or eliminated, such as to edge regions of the upper housing portion 18 remote from the fluid chamber 20. Similarly, and as shown in FIG. 11, the upper housing portion 118 provides enhanced cooling at the fluid chamber 120 such that a cooler region 142 is concentrated at the fluid chamber 120.

Optionally, a thermally conductive element, such as a thermal gel or paste may be placed between the heat generating component and the enclosure to enhance heat dissipation through the enclosure. Further, the enclosure may be formed from any suitable alloy, such as an aluminum alloy, with a range of thermal conductivity to provide an efficient and cost-effective solution. Heat transfer due to the optimization of internal coolant flow and extended surfaces areas is enhanced with the different types of fin structure. The ECU module provides optimized liquid cooling with specific technical constraints and specific power dissipations. That is, the enclosure design that includes fin structure design, the inlet valley fin design and internal pin fin embedded in the straight fins results in enhanced heat transfer. Inlet orifice alignment with the flow channels is designed to reduce turbulence at the entry and to optimize liquid flow distribution that results in optimal flow of liquid coolant in the multi-channel fluid pathway.

Thus, the fluid chamber or fluid jacket provides a multi-channel design to optimize distribution of coolant throughout the fluid jacket in the enclosure. Straight fins are included to guide the flow from inlet to outlet passing through critical IC placement and heat dissipation areas to ensure enhanced heat transfer. This increases the surface area contact for the coolant. Pin fins are embedded along with straight fins to induce turbulence in the flow and increase surface area and therefore enhance the heat transfer to the coolant. Center fins increase the surface area and the height is maintained below the total height of the fluid chamber total height (such as 40 percent of the fluid chamber depth) in order to obtain improved flow throughout the flow paths. The valley fin design at the inlet effectively distributes the flow through all the multi-channel flow paths. The valley fin lip may be lowered in order to improve the flow through the middle channels. Chamfering of the valley fin and straight fins at the entry may reduce the shock loads due to sharp corners. Center fins located downstream may be ramped up in height (such as to 50 percent of the total fluid chamber depth) in order to increase the surface area contact and enhance heat transfer. The inlet orifice may be lifted with respect to the flow base to improve the flow through the valley fin and enhance heat transfer. The entire enclosure may be formed from any suitable material, such as an aluminum alloy die casting with the cover late welded with the enclosure. This reduces the steps needed in manufacturing and satisfies DFM requirements.

In other words, the ECU module enclosure design enhances heat transfer using multi-channel flow paths for coolant flow through the structured fins, that results in lower temperature at the heat dissipated area and IC ensuring safe operation of the IC within allowable limits. The liquid coolant is at a lower temperature than the ECU module, such as an ambient air temperature, and passes through the inlet of the liquid cooling jacket and flows through the multi-channel structured fin. While passing along the heat dissipating fins, heat is transferred from the fins to the liquid coolant due to forced convection. By this way, heat generated inside the ECU will be taken out and the temperature inside the enclosure is reduced or maintained well within the allowable operating temperature limits. The heated coolant passes through the outlet of the cooling jacket. The enclosure may provide a cost effective method for liquid cooling of ECU modules with high power consumption. Manufacturing may be simple and cost effective as it uses die casting and FSW. Optimized distribution of the coolant is achieved. The fin structure improves the heat transfer.

Characteristics of the ECU module described herein may be suitable for use with a vehicular camera module or other type of vehicular ECU module. In other words, the ECU module may include electronic circuitry for a camera module, ADAS ECU module, body control module, door control module, and the like.

The ECU module may utilize characteristics of the modules described in U.S. Pat. Nos. 11,997,371; 11,290,622 and/or U.S. Patent Publication Nos. US-2024-0132003 and/or US-2021-0306538, which are hereby incorporated herein by reference in their entireties.

The ECU module may include an image processor operable to process image data captured by the camera or cameras, such as for detecting objects or other vehicles or pedestrians or the like in the field of view of one or more of the cameras. For example, the image processor may comprise an image processing chip selected from the EYEQ family of image processing chips available from Mobileye Vision Technologies Ltd. of Jerusalem, Israel, and may include object detection software (such as the types described in U.S. Pat. Nos. 7,855,755; 7,720,580 and/or 7,038,577, which are hereby incorporated herein by reference in their entireties), and may analyze image data to detect vehicles and/or other objects. Responsive to such image processing, and when an object or other vehicle is detected, the system may generate an alert to the driver of the vehicle and/or may generate an overlay at the displayed image to highlight or enhance display of the detected object or vehicle, in order to enhance the driver's awareness of the detected object or vehicle or hazardous condition during a driving maneuver of the equipped vehicle.

The vehicle may include any type of sensor or sensors, such as imaging sensors or radar sensors or lidar sensors or ultrasonic sensors or the like. The imaging sensor of the camera may capture image data for image processing and may comprise, for example, a two dimensional array of a plurality of photosensor elements arranged in at least 640 columns and 480 rows (at least a 640×480 imaging array, such as a megapixel imaging array or the like), with a respective lens focusing images onto respective portions of the array. The photosensor array may comprise a plurality of photosensor elements arranged in a photosensor array having rows and columns. The imaging array may comprise a CMOS imaging array having at least 300,000 photosensor elements or pixels, preferably at least 500,000 photosensor elements or pixels and more preferably at least one million photosensor elements or pixels or at least three million photosensor elements or pixels or at least five million photosensor elements or pixels arranged in rows and columns. The imaging array may capture color image data, such as via spectral filtering at the array, such as via an RGB (red, green and blue) filter or via a red/red complement filter or such as via an RCC (red, clear, clear) filter or the like. The logic and control circuit of the imaging sensor may function in any known manner, and the image processing and algorithmic processing may comprise any suitable means for processing the images and/or image data.

For example, the vision system and/or processing and/or camera and/or circuitry may utilize aspects described in U.S. Pat. Nos. 9,233,641; 9,146,898; 9,174,574; 9,090,234; 9,077,098; 8,818,042; 8,886,401; 9,077,962; 9,068,390; 9,140,789; 9,092,986; 9,205,776; 8,917,169; 8,694,224; 7,005,974; 5,760,962; 5,877,897; 5,796,094; 5,949,331; 6,222,447; 6,302,545; 6,396,397; 6,498,620; 6,523,964; 6,611,202; 6,201,642; 6,690,268; 6,717,610; 6,757,109; 6,802,617; 6,806,452; 6,822,563; 6,891,563; 6,946,978; 7,859,565; 5,550,677; 5,670,935; 6,636,258; 7,145,519; 7,161,616; 7,230,640; 7,248,283; 7,295,229; 7,301,466; 7,592,928; 7,881,496; 7,720,580; 7,038,577; 6,882,287; 5,929,786 and/or 5,786,772, and/or U.S. Publication Nos. US-2014-0340510; US-2014-0313339; US-2014-0347486; US-2014-0320658; US-2014-0336876; US-2014-0307095; US-2014-0327774; US-2014-0327772; US-2014-0320636; US-2014-0293057; US-2014-0309884; US-2014-0226012; US-2014-0293042; US-2014-0218535; US-2014-0218535; US-2014-0247354; US-2014-0247355; US-2014-0247352; US-2014-0232869; US-2014-0211009; US-2014-0160276; US-2014-0168437; US-2014-0168415; US-2014-0160291; US-2014-0152825; US-2014-0139676; US-2014-0138140; US-2014-0104426; US-2014-0098229; US-2014-0085472; US-2014-0067206; US-2014-0049646; US-2014-0052340; US-2014-0025240; US-2014-0028852; US-2014-005907; US-2013-0314503; US-2013-0298866; US-2013-0222593; US-2013-0300869; US-2013-0278769; US-2013-0258077; US-2013-0258077; US-2013-0242099; US-2013-0215271; US-2013-0141578 and/or US-2013-0002873, which are all hereby incorporated herein by reference in their entireties. The system may communicate with other communication systems via any suitable means, such as by utilizing aspects of the systems described in U.S. Pat. Nos. 10,071,687; 9,900,490; 9,126,525 and/or 9,036,026, which are hereby incorporated herein by reference in their entireties.

Optionally, the camera may comprise a forward viewing camera, such as disposed at a windshield electronics module (WEM) or the like. The forward viewing camera may utilize aspects of the systems described in U.S. Pat. Nos. 9,896,039; 9,871,971; 9,596,387; 9,487,159; 8,256,821; 7,480,149; 6,824,281 and/or 6,690,268, and/or U.S. Publication Nos. US-2020-0039447; US-2015-0327398; US-2015-0015713; US-2014-0160284; US-2014-0226012 and/or US-2009-0295181, which are all hereby incorporated herein by reference in their entireties.

Changes and modifications in the specifically described embodiments can be carried out without departing from the principles of the invention, which is intended to be limited only by the scope of the appended claims, as interpreted according to the principles of patent law including the doctrine of equivalents.

1. A vehicular electronic control unit (ECU), the vehicular ECU comprising:
a housing;
a printed circuit board (PCB) comprising electronic circuitry;
wherein the PCB is accommodated within the housing;
wherein the electronic circuitry includes a heat-generating electronic component disposed on the PCB, and wherein the heat-generating electronic component, when electrically operated, generates heat within the housing;
a plurality of heat dissipating fins disposed at an exterior side of the housing, and wherein, when heat is generated within the housing by the heat-generating electronic component, the heat is dissipated from within the housing via the plurality of heat dissipating fins;
wherein the plurality of heat dissipating fins is disposed within a fluid chamber at the exterior side of the housing, and wherein coolant flows within the fluid chamber along and between individual heat dissipating fins of the plurality of heat dissipating fins, and wherein heat generated within the housing by the heat-generating electronic component is dissipated from the plurality of heat dissipating fins to the coolant flowing within the fluid chamber;
wherein an inlet port is in fluidic connection with the fluid chamber to provide flow of coolant into the fluid chamber, and wherein an outlet port is in fluidic connection with the fluid chamber to provide flow of coolant out of the fluid chamber; and
wherein the plurality of heat dissipating fins provides a multi-channel flow path for coolant within the fluid chamber between the inlet port and the outlet port.

2. The vehicular ECU of claim 1, wherein the plurality of heat dissipating fins extends along the exterior side of the housing and between the inlet port and the outlet port, and wherein the individual heat dissipating fins of the plurality of heat dissipating fins are spaced from one another to provide respective channels of the multi-channel flow path between adjacent heat dissipating fins of the plurality of heat dissipating fins.

3. The vehicular ECU of claim 1, wherein the multi-channel flow path comprises a plurality of channels, and wherein each channel of the plurality of channels is disposed between respective adjacent individual heat dissipating fins of the plurality of heat dissipating fins, and wherein the plurality of channels extends within the fluid chamber between the inlet port and the outlet port.

4. The vehicular ECU of claim 1, wherein the individual heat dissipating fins of the plurality of heat dissipating fins cooperate to distribute coolant to respective channels of the multi-channel flow path and guide coolant along the multi-channel flow path from the inlet port toward the outlet port.

5. The vehicular ECU of claim 1, wherein the plurality of heat dissipating fins comprises (i) at least one first heat dissipating fin having a uniform thickness along a length of the at least one first heat dissipating fin and (ii) at least one second heat dissipating fin having a varied thickness along a length of the at least one second heat dissipating fin.

6. The vehicular ECU of claim 5, wherein the plurality of heat dissipating fins comprises first heat dissipating fins and second heat dissipating fins that extend substantially parallel to one another between the inlet port and the outlet port.

7. The vehicular ECU of claim 5, wherein the at least one second heat dissipating fin comprises a plurality of protrusions along the length of the at least one second heat dissipating fin.

8. The vehicular ECU of claim 5, wherein the at least one first heat dissipating fin comprises a first height relative to the exterior side of the housing, and wherein the at least one second heat dissipating fin comprises a second height relative to the exterior side of the housing, and wherein the second height is greater than the first height.

9. The vehicular ECU of claim 1, wherein the multi-channel flow path comprises at least one U-shaped flow path between the inlet port and the outlet port.

10. The vehicular ECU of claim 1, wherein a second plurality of heat dissipating fins is disposed at the exterior side of the housing and not within the fluid chamber.

11. The vehicular ECU of claim 1, wherein the heat-generating electronic component comprises a data processor operable to process data captured by at least one sensor of a vehicle equipped with the vehicular ECU.

12. The vehicular ECU of claim 11, wherein the at least one sensor of the vehicle comprises at least one camera of the vehicle.

13. The vehicular ECU of claim 11, wherein the at least one sensor of the vehicle comprises at least one radar sensor of the vehicle.

14. A vehicular electronic control unit (ECU), the vehicular ECU comprising:
a housing;
a printed circuit board (PCB) comprising electronic circuitry;
wherein the PCB is accommodated within the housing;
wherein the electronic circuitry includes a heat-generating electronic component disposed on the PCB, and wherein the heat-generating electronic component, when electrically operated, generates heat within the housing;
a plurality of heat dissipating fins disposed at an exterior side of the housing, and wherein, when heat is generated within the housing by the heat-generating electronic component, the heat is dissipated from within the housing via the plurality of heat dissipating fins;
wherein the plurality of heat dissipating fins comprises (i) at least one first heat dissipating fin having a uniform thickness along a length of the at least one first heat dissipating fin and (ii) at least one second heat dissipating fin having a varied thickness along a length of the at least one second heat dissipating fin;
wherein the plurality of heat dissipating fins is disposed within a fluid chamber at the exterior side of the housing, and wherein coolant flows within the fluid chamber along and between individual heat dissipating fins of the plurality of heat dissipating fins, and wherein heat generated within the housing by the heat-generating electronic component is dissipated from the plurality of heat dissipating fins to the coolant flowing within the fluid chamber;
wherein an inlet port is in fluidic connection with the fluid chamber to provide flow of coolant into the fluid chamber, and wherein an outlet port is in fluidic connection with the fluid chamber to provide flow of coolant out of the fluid chamber;
wherein the plurality of heat dissipating fins provides a multi-channel flow path for coolant within the fluid chamber between the inlet port and the outlet port; and
wherein the plurality of heat dissipating fins extends along the exterior side of the housing and between the inlet port and the outlet port, and wherein the individual heat dissipating fins of the plurality of heat dissipating fins are spaced from one another to provide respective channels of the multi-channel flow path between adjacent heat dissipating fins of the plurality of heat dissipating fins.

15. The vehicular ECU of claim 14, wherein the at least one second heat dissipating fin comprises a plurality of protrusions along the length of the at least one second heat dissipating fin.

16. The vehicular ECU of claim 14, wherein the at least one first heat dissipating fin comprises a first height relative to the exterior side of the housing, and wherein the at least one second heat dissipating fin comprises a second height relative to the exterior side of the housing, and wherein the second height is greater than the first height.

17. The vehicular ECU of claim 14, wherein the multi-channel flow path comprises at least one U-shaped flow path between the inlet port and the outlet port.

18. A vehicular electronic control unit (ECU), the vehicular ECU comprising:
a housing;
a printed circuit board (PCB) comprising electronic circuitry;
wherein the PCB is accommodated within the housing;
wherein the electronic circuitry includes a heat-generating electronic component disposed on the PCB, and wherein the heat-generating electronic component, when electrically operated, generates heat within the housing;
wherein the heat-generating electronic component comprises a data processor operable to process data captured by at least one sensor of a vehicle equipped with the vehicular ECU;
a plurality of heat dissipating fins disposed at an exterior side of the housing, and wherein, when heat is generated within the housing by the heat-generating electronic component, the heat is dissipated from within the housing via the plurality of heat dissipating fins;
wherein the plurality of heat dissipating fins is disposed within a fluid chamber at the exterior side of the housing, and wherein coolant flows within the fluid chamber along and between individual heat dissipating fins of the plurality of heat dissipating fins, and wherein heat generated within the housing by the heat-generating electronic component is dissipated from the plurality of heat dissipating fins to the coolant flowing within the fluid chamber;
wherein an inlet port is in fluidic connection with the fluid chamber to provide flow of coolant into the fluid chamber, and wherein an outlet port is in fluidic connection with the fluid chamber to provide flow of coolant out of the fluid chamber;
wherein the plurality of heat dissipating fins provides a multi-channel flow path for coolant within the fluid chamber between the inlet port and the outlet port;
wherein the individual heat dissipating fins of the plurality of heat dissipating fins cooperate to distribute coolant to respective channels of the multi-channel flow path and guide coolant along the multi-channel flow path from the inlet port toward the outlet port; and
wherein the multi-channel flow path comprises at least one U-shaped flow path between the inlet port and the outlet port.

19. The vehicular ECU of claim 18, wherein the plurality of heat dissipating fins comprises (i) at least one first heat dissipating fin having a uniform thickness along a length of the at least one first heat dissipating fin and (ii) at least one second heat dissipating fin having a varied thickness along a length of the at least one second heat dissipating fin.

20. The vehicular ECU of claim 18, wherein the at least one sensor of the vehicle comprises at least one selected from the group consisting of (i) at least one camera of the vehicle and (ii) at least one radar sensor of the vehicle.
